(19) United States
(12) Patent Application Publication
(10) Pub. No.: US 2024/0297478 A1
(43) Pub. Date: Sep. 5, 2024

(54) OPTICAL ENGINE MODULE

(71) Applicant: Qisda Corporation, Taoyuan City (TW)

(72) Inventors: Wen-Chung Ho, Taoyuan City (TW); Tsung-Hsun Wu, Taoyuan City (TW); Cheng-Hsun Wu, Taoyuan City (TW)

(73) Assignee: Qisda Corporation, Taoyuan City (TW)

(21) Appl. No.: 18/415,663

(22) Filed: Jan. 18, 2024

(30) Foreign Application Priority Data
Mar. 1, 2023 (CN) 202310185353.2

(51) Int. Cl. H01S 5/02255; H01S 5/02218

(52) U.S. Cl. CPC H01S 5/02255; H01S 5/02218

(57) ABSTRACT

An optical engine module including a plastic housing, a first light source, and a light path turning unit is disclosed. The plastic housing has a first light incident side and a light emerging side. The light emerging side is adjacent to the light incident side. The first light source is disposed on the first light incident side, and configured to emit a first beam. The light path turning unit is disposed in the plastic housing, and configured to turn and transmit the first beam to the light emerging side. A material of the light path turning unit includes metal.

### CROSS-REFERENCE TO RELATED APPLICATION

This application claims the priority benefit of China application serial no. 202310185353.2, filed on Mar. 1, 2023. The entirety of the above-mentioned patent application is hereby incorporated by reference herein and made a part of this specification.

### BACKGROUND

### Technical Field

The invention relates to an optical module, and more particularly, to an optical engine module.

### Description of Related Art

Illumination system may be used in many fields, for example, it may be used to illuminate a light valve in a projection device to generate an image beam, or it may also be used for other lighting purposes. Along with advancement of optoelectronic technology, illumination systems using lasers as light-emitting elements have been developed.

In the illumination system, the optical element is usually placed in an optical element housing, while a laser diode is located in a laser box. Generally, both of the laser box and the optical element housing are made of metal, so that when the laser box is assembled on the optical element housing, a plastic part is required to be disposed between the laser box and the optical element housing, so that the laser box is at a primary side and the optical element housing is maintained at a secondary side, thereby avoiding safety issues.

However, by using the plastic part, in addition to increasing the cost, if a dustproof material is used to prevent dust from entering the optical element housing, the dustproof material is required to be disposed between the laser box and the plastic part and between the plastic part and the optical element housing. In this way, more dustproof materials will be added, which further increases the cost.

### SUMMARY

The invention provides an optical engine module, which may effectively reduce cost.

An embodiment of the invention provides an optical engine module including a plastic housing, a first light source, and a light path turning unit. The plastic housing has a first light incident side and a light emerging side. The light emerging side is adjacent to the first light incident side. The first light source is disposed on the first light incident side, and configured to emit a first beam. The light path turning unit is disposed in the plastic housing, and configured to turn and transmit the first beam to the light emerging side. A material of the light path turning unit includes metal.

In the optical engine module according to the embodiment of the invention, since the plastic housing is used to fix the light path turning unit and the first light source, the cost is effectively reduced. In addition, the plastic housing may be directly fixed to other optical element housing made of metal without safety issues, and there is no need to use additional plastic parts to avoid the safety issues, which may also reduce costs. In addition, if it is required to use a dustproof material, only one set of the dustproof material is required to be disposed between the plastic housing and the optical element housing, compared with the prior art that uses additional plastic parts and requires two sets of dustproof materials, the optical engine module of the embodiment of the invention may further save costs.

### BRIEF DESCRIPTION OF THE DRAWINGS

FIG. 1A is a schematic cross-sectional view of an optical engine module according to an embodiment of the invention.

FIG. 1B is a schematic view of an appearance of the optical engine module of FIG. 1A.

FIG. 2A is a schematic cross-sectional view of an optical engine module according to another embodiment of the invention.

FIG. 2B and FIG. 2C are schematic perspective views of some components of the optical engine module of FIG. 2A.

FIG. 2D is a front view of the optical engine module of FIG. 2A viewed from a light emerging opening of a plastic housing.

FIG. 3 is a schematic perspective view of some components of an optical engine module according to still another embodiment of the invention.

FIG. 4 is a schematic perspective view of some components of an optical engine module according to yet another embodiment of the invention.

FIG. 5 is a schematic cross-sectional view of a junction of a plastic housing and an optical element housing and a dustproof material in an optical engine module according to another embodiment of the invention.

### DESCRIPTION OF THE EMBODIMENTS

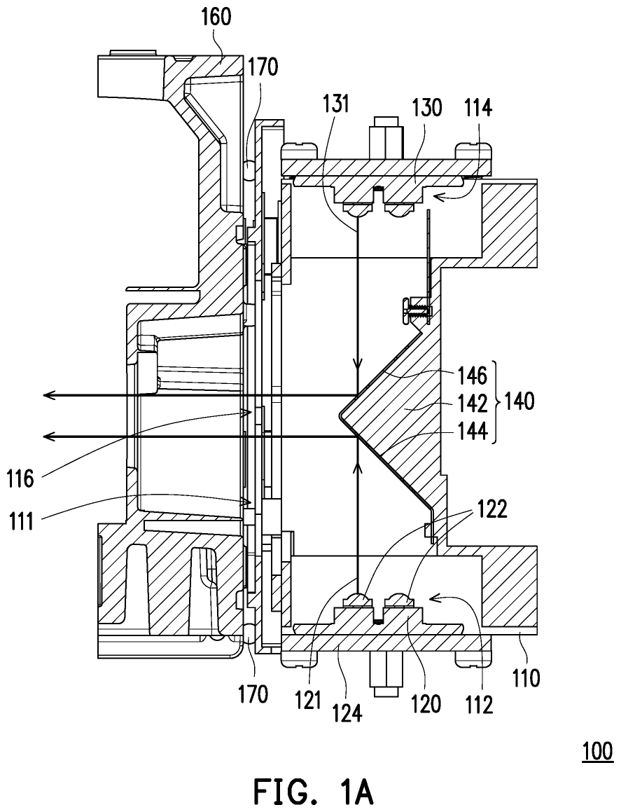

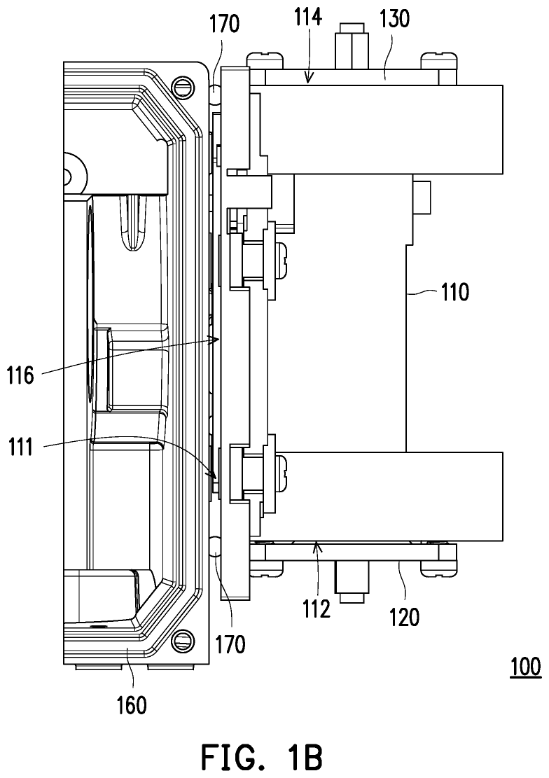

FIG. 1A is a schematic cross-sectional view of an optical engine module according to an embodiment of the invention, and FIG. 1B is a schematic view of an appearance of the optical engine module of FIG. 1A. Referring to FIG. 1A and FIG. 1B, an optical engine module 100 of the embodiment includes a plastic housing 110, a first light source 120 and a light path turning unit 140. The plastic housing 110 has a first light incident side 112 and a light emerging side 116, where the light emerging side 116 is adjacent to the first light incident side 112. The first light source 120 is disposed on the first light incident side 112 and configured to emit a first beam 121. The light path turning unit 140 is disposed in the plastic housing 110 and configured to turn and transmit the first beam 121 to the light emerging side 116, where a material of the light path turning unit 140 includes metal.

In the embodiment, a direction that the first light incident side 112 faces is perpendicular to a direction that the light emerging side 116 faces, but the invention is not limited thereto. In addition, in the embodiment, the light path turning unit 140 includes a metal base 142 and a first reflective element 144, where the first reflective element 144 is disposed on the metal base 142, and is configured to reflect the first beam 121 to the light emerging side 116, where the first reflective element 144 is disposed obliquely relative to the first beam 121.

In the embodiment, the plastic housing 110 further has a second light incident side 114, where the first light incident side 112 is opposite to the second light incident side 114, and the light emerging side 116 is adjacent to the second light incident side 114. The optical engine module 100 further includes a second light source 130 disposed on the second light incident side 114 for emitting a second beam 131, where the light path turning unit 140 turns and transmits the second beam 131 to the light emerging side 116.

In the embodiment, the light path turning unit 140 further includes a second reflective element 146, which is disposed on the metal base 142, and is configured to reflect the second beam 131 to the light emerging side 116, where an inclination direction of the first reflective element 144 relative to the light emerging side 116 is opposite to an inclination direction of the second reflective element 146 relative to the light emerging side 116. Moreover, in the embodiment, the first reflective element 144 and the second reflective element 146 are configured in a V shape, and the light path turning unit 140 may be regarded as a light combining unit that combines the first beam 121 and the second beam 131. In the embodiment, the first light source 120, the second light source 130 and the light path turning unit 140 are fixed at different positions of the plastic housing 110 and separated from each other. In the embodiment, the first reflective element 114 and the second reflective element 146 are, for example, reflective mirrors or reflective films.

In the embodiment, each of the first light source 120 and the second light source 130 is a laser package, and the laser package includes a metal substrate 124 and at least one laser diode 122 (a plurality of laser diodes 122 are taken as an example in FIG. 1A) disposed on the metal substrate 124. In the embodiment, the first beam 121 and the second beam 131 are, for example, laser beams.

In the embodiment, the optical engine module 100 further includes an optical element housing 160, where the light emerging side 116 of the plastic housing 110 is connected to the optical element housing 160, and the optical element housing 160 is a metal housing. The interior of the optical element housing 160 may be provided with, for example, a phosphor plate or a phosphor wheel, a dichroic mirror or a light-splitting mirror, a homogenizing element, a color wheel, a prism, a light valve, a lens or a combination thereof, but the invention is not limited thereto.

In the embodiment, the optical engine module 100 further includes a dustproof material 170 connecting the optical element housing 160 and the plastic housing 110. The plastic housing 110 has a light emerging opening 111 on the light emerging side 116, and the dustproof material 170 surrounds the light emerging opening 111. In the embodiment, the dustproof material 170 includes rubber or sponge.

In the optical engine module 100 of the embodiment, since the plastic housing 110 is adopted to fix the light path turning unit 140, the first light source 120, and the second light source 130, the cost may be effectively reduced. In addition, the plastic housing 110 may be directly fixed to the other optical element housing 160 made of metal without safety issues, and there is no need to use additional plastic parts to avoid the safety issues, which may also reduce the costs. In addition, if the dustproof material 170 is required to be used, only one set of the dustproof material 170 is required to be disposed between the plastic housing 110 and the optical element housing 160. Compared with the prior art that uses additional plastic parts and requires two sets of the dustproof materials, the optical engine module 100 of the embodiment may further save costs.

On the other hand, heat generated by the first beam 121 and the second beam 131 irradiating the light path turning unit 140 may be conducted to the outside through the metal base 142 to assist heat dissipation.

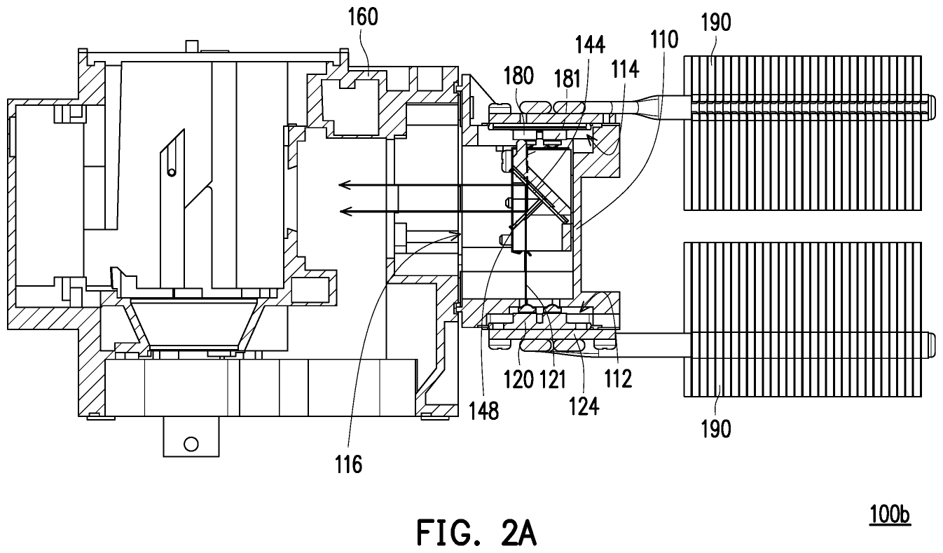

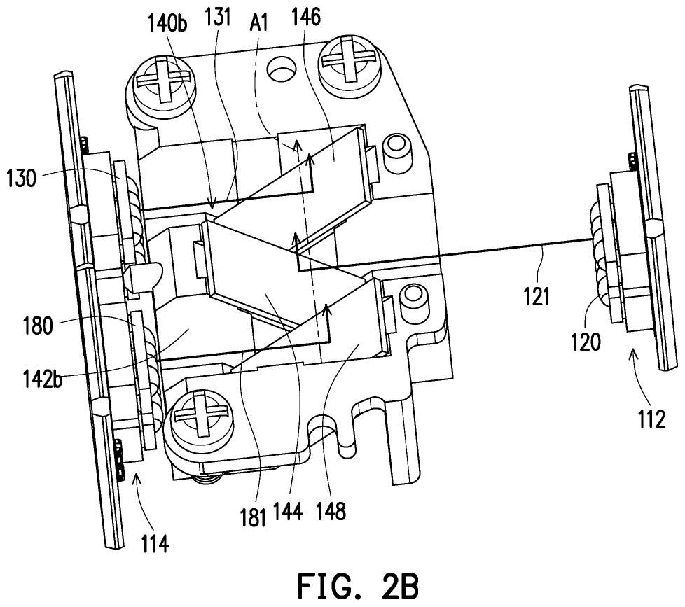

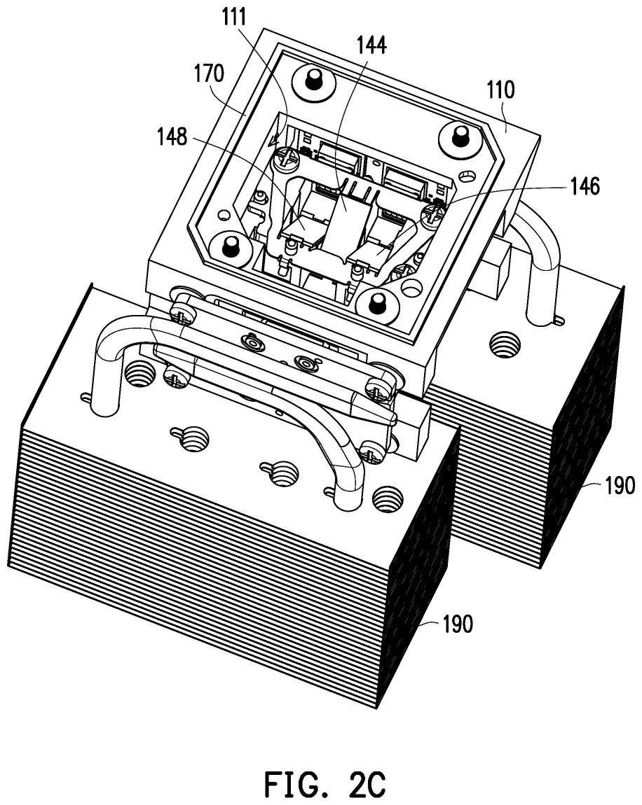

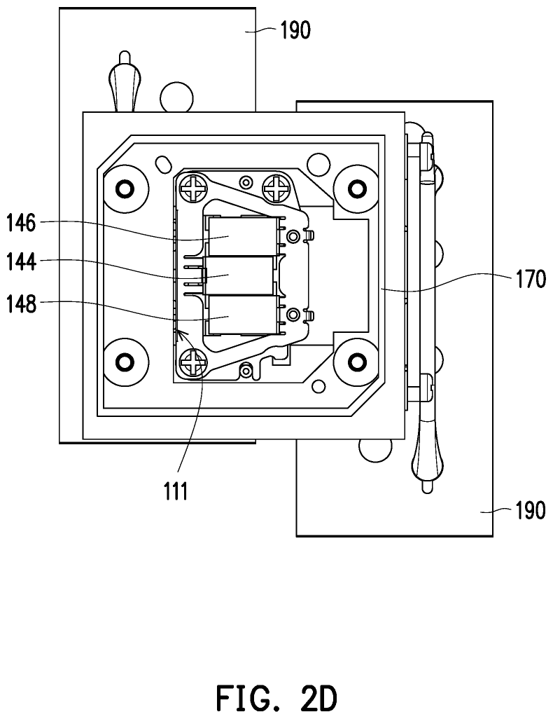

FIG. 2A is a schematic cross-sectional view of an optical engine module according to another embodiment of the invention. FIG. 2B and FIG. 2C are schematic perspective views of some components of the optical engine module of FIG. 2A, and FIG. 2D is a front view of the optical engine module of FIG. 2A viewed from the light emerging opening of the plastic housing. Referring to FIG. 2A to FIG. 2D, an optical engine module 100b of the embodiment is similar to the optical engine module 100 of FIG. 1A, and differences there between are as follows. In the embodiment, the first reflective element 144 and the second reflective element 146 are arranged in an arrangement direction A1, the arrangement direction A1 is perpendicular to a direction from the first light incident side 112 to the second light incident side 114, and the first reflective element 144 and the second reflective element 146 are cross-arranged, i.e., arranged in an X-shape as viewing along the arrangement direction A1.

In the embodiment, the optical engine module 100b further includes a third light source 180 configured on the second light incident side 114, and configured to emit a third beam 181, where the light path turning unit 140b further includes a third reflective element 148 disposed on the metal base 142b and configured to reflect the third beam 181 to the light emerging side 116. The third reflective element 148, the first reflective element 144, and the second reflective element 146 are arranged in the arrangement direction A1, and the third reflective element 148 and the first reflective element 144 are cross-arranged i.e., arranged in an X-shape as viewing along the arrangement direction A1. The light path turning unit 140b of the embodiment may also achieve the effect of combining the first beam 121, the second beam 131 and the third beam 181.

In the embodiment, the optical engine module 100b may further include a plurality of cooling fins 190 connected to metal substrates (such as the metal substrate 124) of the first light source 120, the second light source 130 and the third light source 180, so that the first light source 120, the second light source 130 and the third light source 180 may achieve a better cooling effect. In addition, it may be seen from FIG. 2C that the dustproof material 170 surrounds the light emerging opening 111 of the plastic housing 110.

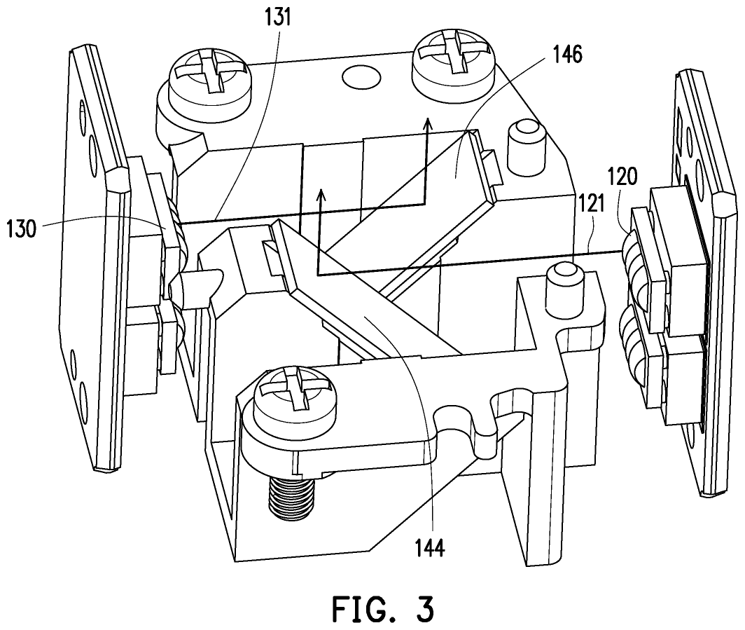

FIG. 3 is a schematic perspective view of some components of an optical engine module according to still another embodiment of the invention. Referring to FIG. 3, the optical engine module of the embodiment is similar to the optical engine module of FIG. 2A, and a difference there between is that the optical engine module of the embodiment includes the first reflective element 144 and the second reflective element 146, but does not include the third reflective element 148 as shown in FIG. 2B, and the optical engine module of the embodiment includes the first light source 120 and the second light source 130, but does not include the third light source 180 as shown in FIG. 2B. Where, the configurations of the first reflective element 144, the second reflective element 146, the first light source 120 and the second light source 130 are as that described in the embodiment of FIG. 2B, and details thereof are not repeated here. The first reflective element 144 and the second reflective element 146 in the embodiment may achieve the effect of combining the first beam 121 and the second beam 131.

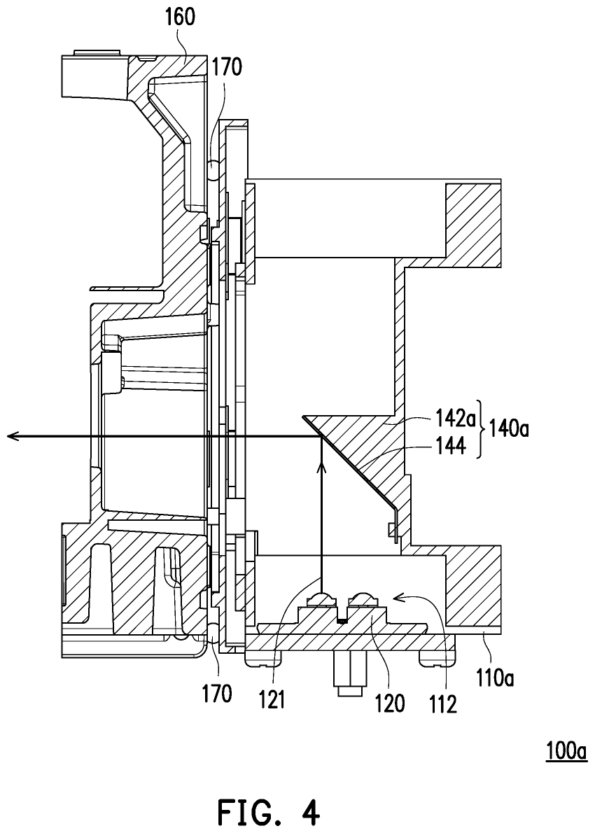

FIG. 4 is a schematic perspective view of some components of an optical engine module according to yet another embodiment of the invention. Referring to FIG. 4, an optical engine module 100a of the embodiment is similar to the optical engine module 100 of FIG. 1A, and differences there between are as follows. In the optical engine module 100a of the embodiment, the plastic housing 110a has the first light incident side 112 and the light emerging side 116, but does not have the second light incident side 114 as shown in FIG. 1A. The optical engine module 100a has the first light source 120, but does not have the second light source 130 as shown in FIG. 1A. In addition, in the embodiment, the light path turning unit 140a has the first reflective element 144 but does not have the second reflective element 146, and the metal base 142a may be made into a shape that is only required to support the first reflective element 144. The light path turning unit 140a of the embodiment may achieve an effect of turning a light path of the first beam 121.

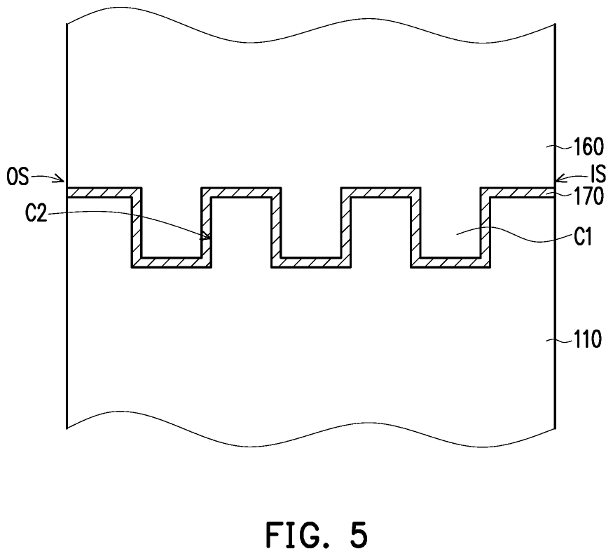

FIG. 5 is a schematic cross-sectional view of a junction of a plastic housing and an optical element housing and a dustproof material in the optical engine module according to another embodiment of the invention. Referring to FIG. 5, the junction of the plastic housing 110 and the optical element housing 160 in the optical engine module in each of the above-mentioned embodiments may be changed to a structure shown in FIG. 5 to form the optical engine modules of other embodiments. Specifically, in the embodiment, at a place where the optical element housing 160 is connected to the plastic housing 110, the optical element housing 160 is provided with at least one first fitting portion C1 (a plurality of first fitting portions C1 are adopted in FIG. 5), the plastic housing 110 is provided with at least one second fitting portion C2 (a plurality of second fitting portions C2 are adopted in FIG. 5), the first fitting portions C1 and the second fitting portions C2 are fitted with each other, and the dustproof material 170 is disposed between the first fitting portions C1 and the second fitting portions C2.

In the embodiment, the at least one first fitting portion C1 is a plurality of first fitting portion C1 sequentially arranged from the outside of the optical element housing 160 (such as an outside OS of the optical element housing 160) to the inside of the optical element housing 160 (such as an inside IS of the optical element housing 160), and the at least one second fitting portion C2 is a plurality of second fitting portions C2 arranged sequentially from the outside of the plastic housing 110 to the inside of the plastic housing 110. In addition, one of the first fitting portions C1 and the second fitting portions C2 are protrusions, and the other one of the first fitting portions C1 and the second fitting portions C2 is depressions, and in FIG. 5, the first fitting portions C1 are protrusions, and the second fitting portions C2 are depressions. Based on the design of the first fitting portions C1 and the second fitting portions C2, if external dust is about to enter the interior of the optical element housing 160 and the plastic housing 110 through a junction between the optical element housing 160 and the plastic housing 110 (i.e., the dust on the outside OS enters the inside IS through the junction between the optical element housing 160 and the plastic housing 110), it needs to go through a roundabout path to reach, and this roundabout path is further provided with the dustproof material 170 to block dust. Therefore, such a design can further enhance the effectiveness of dust prevention.

In summary, in the optical engine module of the embodiment of the invention, since the plastic housing is used to fix the light path turning unit and the first light source, the cost is effectively reduced. In addition, the plastic housing may be directly fixed to other optical element housing made of metal without safety issues, and there is no need to use additional plastic parts to avoid the safety issues, which may also reduce costs. In addition, if it is required to use the dustproof material, only one set of the dustproof material is required to be disposed between the plastic housing and the optical element housing, compared with the prior art that uses additional plastic parts and requires two sets of dustproof materials, the optical engine module of the embodiment of the invention may further save costs.

What is claimed is:

1. An optical engine module, comprising:
a plastic housing having a first light incident side and a light emerging side, wherein the light emerging side is adjacent to the first light incident side;
a first light source disposed on the first light incident side, and configured to emit a first beam; and
a light path turning unit disposed in the plastic housing, and configured to turn and transmit the first beam to the light emerging side, wherein a material of the light path turning unit comprises metal.

2. The optical engine module according to claim 1, wherein the light path turning unit comprises:
a metal base; and
a first reflective element disposed on the metal base, and configured to reflect the first beam to the light emerging side, wherein the first reflective element is obliquely disposed relative to the first beam.

3. The optical engine module according to claim 1, wherein a direction that the first light incident side faces is perpendicular to a direction that the light emerging side faces.

4. The optical engine module according to claim 1, wherein the plastic housing further has a second light incident side, the first light incident side is opposite to the second light incident side, the light emerging side is adjacent to the second light incident side, the optical engine module further comprises a second light source disposed on the second light incident side and configured to emit a second beam, and the light path turning unit turns and transmits the second beam to the light emerging side.

5. The optical engine module according to claim 4, wherein the light path turning unit comprises:
a metal base;
a first reflective element disposed on the metal base, and configured to reflect the first beam to the light emerging side; and
a second reflective element disposed on the metal base and configured to reflect the second beam to the light emerging side, wherein an inclination direction of the first reflective element relative to the light emerging side is opposite to an inclination direction of the second reflective element relative to the light emerging side.

6. The optical engine module according to claim 5, wherein the first reflective element and the second reflective element are disposed in a V shape.

7. The optical engine module according to claim 5, wherein the first reflective element and the second reflective element are arranged in an arrangement direction, the arrangement direction is perpendicular to a direction from the first light incident side to the second light incident side, and the first reflective element and the second reflective element are cross-arranged when viewed along the arrangement direction.

8. The optical engine module according to claim 7, further comprising a third light source disposed on the second light incident side, and configured to emit a third beam, wherein the light path turning unit further comprises a third reflective element disposed on the metal base, and configured to reflect the third beam to the light emerging side, the third reflective element, the first reflective element, and the second reflective element are arranged in the arrangement direction, and the third reflective element and the first reflective element are cross-arranged when viewed along the arrangement direction.

9. The optical engine module according to claim 1, wherein the first light source is a laser package.

10. The optical engine module according to claim 9, wherein the laser package comprises at least one laser diode.

11. The optical engine module according to claim 1, further comprising an optical element housing, wherein the light emerging side of the plastic housing is connected to the optical element housing, and the optical element housing is a metal housing.

12. The optical engine module according to claim 11, further comprising a dustproof material connecting the optical element housing and the plastic housing.

13. The optical engine module according to claim 12, wherein the plastic housing has a light emerging opening on the light emerging side, and the dustproof material surrounds the light emerging opening.

14. The optical engine module according to claim 12, wherein at a place where the optical element housing is connected to the plastic housing, the optical element housing is provided with at least one first fitting portion, the plastic housing is provided with at least one second fitting portion, the at least one first fitting portion and the at least one second fitting portion are fitted with each other, and the dustproof material is disposed between the first fitting portion and the second fitting portion.

15. The optical engine module according to claim 14, wherein the at least one first fitting portion is a plurality of first fitting portions sequentially arranged from an outside of the optical element housing to an inside of the optical element housing, and the at least one second fitting portion is a plurality of second fitting portions sequentially arranged from an outside of the plastic housing to an inside of the plastic housing.

16. The optical engine module according to claim 14, wherein one of the first fitting portion and the second fitting portion is a protrusion, and the other one of the first fitting portion and the second fitting portion is a depression.

17. The optical engine module according to claim 12, wherein the dustproof material comprises rubber or sponge.

18. The optical engine module according to claim 1, wherein the first light source and the light path turning unit are fixed at different positions of the plastic housing and separated from each other.
